(19) United States
(12) Patent Application Publication
(10) Pub. No.: US 2025/0227919 A1
(43) Pub. Date: Jul. 10, 2025

(54) SEMICONDUCTOR DEVICE

(71) Applicant: Samsung Electronics Co., Ltd., Suwon-si (KR)

(72) Inventors: Junghwan HUH, Suwon-si (KR); Yongro SHIN, Suwon-si (KR); Youngwook PARK, Suwon-si (KR)

(73) Assignee: Samsung Electronics Co., Ltd., Suwon-si (KR)

(21) Appl. No.: 18/763,349

(22) Filed: Jul. 3, 2024

(30) Foreign Application Priority Data
Jan. 5, 2024 (KR) 10-2024-0002221

(51) Int. Cl. H10B 12/00; H01L 23/528

(52) U.S. Cl. CPC H10B 12/488; H01L 23/5283

(57) ABSTRACT

A semiconductor device may include a substrate, an active pattern on the substrate, and a word line structure crossing the active pattern. The word line structure may include a word line, a capping pattern on the word line, and a protection insulating pattern between the word line and the capping pattern.

### CROSS-REFERENCE TO RELATED APPLICATIONS

This U.S. non-provisional patent application claims priority under 35 U.S.C. § 119 to Korean Patent Application No. 10-2024-0002221, filed on Jan. 5, 2024, in the Korean Intellectual Property Office, the entire contents of which are hereby incorporated by reference.

### BACKGROUND

The present inventive concepts relate to semiconductor devices, and in particular, to semiconductor memory devices.

Due to their small-sized, multifunctional, and/or low-cost characteristics, semiconductor devices are being esteemed as important elements in the electronics industry. The semiconductor devices are classified into a semiconductor memory device for storing data, a semiconductor logic device for processing data, and a hybrid semiconductor device including both of memory and logic elements.

Due to the recent increasing demand for electronic devices with a fast speed and/or low power consumption, the semiconductor device requires a fast operating speed and/or a low operating voltage. To satisfy the requirement, it is necessary to increase an integration density of the semiconductor device. As the integration density of the semiconductor device increases, the electrical and reliability characteristics of the semiconductor device may be deteriorated. Accordingly, many studies are being conducted to improve the electrical and reliability characteristics of the semiconductor device.

### SUMMARY

Some example embodiments of the inventive concepts provide a semiconductor device with improved electrical and reliability characteristics.

According to some example embodiments of the inventive concepts, a semiconductor device may include a substrate, an active pattern on the substrate, and a word line structure crossing the active pattern. The word line structure may include a word line, a capping pattern on the word line, and a protection insulating pattern between the word line and the capping pattern.

According to some example embodiments of the inventive concepts, a semiconductor device may include a substrate, a device isolation pattern on the substrate, an active pattern on the substrate, the active layer enclosed by the device isolation pattern, and a word line structure crossing the device isolation pattern and the active pattern in a first direction, the first direction parallel to a top surface of the substrate. The word line structure may include a word line, a capping pattern on the word line, a protection insulating pattern on the word line, such that the protection insulating pattern encloses bottom and side surfaces of the capping pattern. The word line may have a first width in a second direction, the second direction is parallel to the top surface of the substrate and is perpendicular to the first direction, and a bottom surface of the capping pattern may have a second width in the second direction. The second width may be smaller than the first width.

According to some example embodiments of the inventive concepts, a semiconductor device may include a substrate, a device isolation pattern on the substrate, an active pattern on the substrate, the active pattern enclosed by the device isolation pattern, a word line structure crossing the active pattern and the device isolation pattern in a first direction parallel to a top surface of the substrate, a bit line on the active pattern and extended in a second direction crossing the first direction, a bit line contact between the active pattern and the bit line, a storage node contact on the active pattern, a landing pad on the storage node contact, and a capacitor on the landing pad. The word line structure may include a first conductive pattern, a second conductive pattern on the first conductive pattern, a capping pattern on the second conductive pattern, and a protection insulating pattern between the second conductive pattern and the capping pattern. The protection insulating pattern may include a first vertical portion, a second vertical portion, and a horizontal portion connecting the first vertical portion to the second vertical portion. The first and second vertical portions may be in contact with a side surface of the capping pattern, and the horizontal portion may be in contact with a bottom surface of the capping pattern.

### BRIEF DESCRIPTION OF THE DRAWINGS

FIG. 1 is a block diagram illustrating a semiconductor device according to some example embodiments of the inventive concepts.

FIG. 2 is a plan view illustrating a semiconductor device according to some example embodiments of the inventive concepts and corresponding to a portion ‘P1’ of FIG. 1.

FIGS. 3A, 3B, and 3C are sectional views, which are taken along lines A-A′, B-B′, and C-C′, respectively, of FIG. 2 to illustrate a semiconductor device according to some example embodiments of the inventive concepts.

FIG. 4 is an enlarged view corresponding to a portion ‘P2’ of FIG. 3A according to some example embodiments of the inventive concepts.

FIGS. 5A, 5B, 6A, 6B, 7A, 7B, 8A, 8B, 9A, 9B, 10A, 10B, 11A, 11B, 12A, 12B, 13A, and 13B are sectional views illustrating a process of fabricating a semiconductor device, according to some example embodiments of the inventive concepts.

### DETAILED DESCRIPTION

Some example embodiments of the inventive concepts will now be described more fully with reference to the accompanying drawings, in which some example embodiments are shown. The drawings and description are to be regarded as illustrative in nature and not restrictive. Like reference numerals designate like elements throughout the specification. Size and thickness of each constituent element in the drawings are arbitrarily illustrated for better understanding and ease of description, the following embodiments are not limited thereto.

Throughout the specification, the term “connected” does not mean only that two or more constituent components are directly connected, but may also mean that two or more constituent components are indirectly connected through another constituent component. In addition, unless explicitly described to the contrary, the word “comprise”, and variations such as “comprises” or “comprising”, will be understood to imply the inclusion of stated elements but not the exclusion of any other elements.

It will be understood that when an element such as a layer, film, region, or substrate is referred to as being “on” another element, it can be directly on the other element or intervening elements may also be present. In contrast, when an element is referred to as being “directly on” another element, there are no intervening elements present. Further, when an element is referred to as being “above” or “on” a reference element, it can be positioned above or below the reference element, and it is not necessarily referred to as being positioned “above” or “on” in a direction opposite to gravity.

Further, throughout the specification, the phrase “in a plan view” or “on a plane” means viewing a target portion from the top, and the phrase “in a cross-sectional view” or “on a cross-section” means viewing a cross-section formed by vertically cutting a target portion from the side.

It will be understood that elements and/or properties thereof (e.g., structures, surfaces, directions, or the like), which may be referred to as being “perpendicular,” “parallel,” “coplanar,” or the like with regard to other elements and/or properties thereof (e.g., structures, surfaces, directions, or the like) may be “perpendicular,” “parallel,” “coplanar,” or the like or may be “substantially perpendicular,” “substantially parallel,” “substantially coplanar,” respectively, with regard to the other elements and/or properties thereof.

Elements and/or properties thereof (e.g., structures, surfaces, directions, or the like) that are “substantially perpendicular”, “substantially parallel”, or “substantially coplanar” with regard to other elements and/or properties thereof will be understood to be “perpendicular”, “parallel”, or “coplanar”, respectively, with regard to the other elements and/or properties thereof within manufacturing tolerances and/or material tolerances and/or have a deviation in magnitude and/or angle from “perpendicular”, “parallel”, or “coplanar”, respectively, with regard to the other elements and/or properties thereof that is equal to or less than 10% (e.g., a. tolerance of ±10%).

It will be understood that elements and/or properties thereof may be recited herein as being “identical”, “the same”, or “equal” as other elements, and it will be further understood that elements and/or properties thereof recited herein as being “identical” to, “the same” as, or “equal” to other elements may be “identical” to, “the same” as, or “equal” to or “substantially identical” to, “substantially the same” as or “substantially equal” to the other elements and/or properties thereof. Elements and/or properties thereof that are “substantially identical” to, “substantially the same” as or “substantially equal” to other elements and/or properties thereof will be understood to include elements and/or properties thereof that are identical to, the same as, or equal to the other elements and/or properties thereof within manufacturing tolerances and/or material tolerances. Elements and/or properties thereof that are identical or substantially identical to, equal to or substantially equal to, and/or the same or substantially the same as other elements and/or properties thereof may be structurally the same or substantially the same, functionally the same or substantially the same, and/or compositionally the same or substantially the same. While the term “same,” “equal” or “identical” may be used in description of some example embodiments, it should be understood that some imprecisions may exist. Thus, when one element or property is referred to as being identical to, equal to, or the same as another element or property, it should be understood that the element or property is the same as another element or property within a desired manufacturing or operational tolerance range (e.g., ±10%).

It will be understood that elements and/or properties thereof described herein as being “substantially” the same, equal, and/or identical encompasses elements and/or properties thereof that have a relative difference in magnitude that is equal to or less than 10%. Further, regardless of whether elements and/or properties thereof are modified as “substantially,” it will be understood that these elements and/or properties thereof should be construed as including a manufacturing or operational tolerance (e.g., ±10%) around the stated elements and/or properties thereof.

When the terms “about” or “substantially” are used in this specification in connection with a numerical value, it is intended that the associated numerical value includes a manufacturing or operational tolerance (e.g., ±10%) around the stated numerical value. Moreover, when the words “about” and “substantially” are used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., ±10%) around the stated numerical values or shapes. When ranges are specified, the range includes all values therebetween such as increments of 0.1%.

As described herein, when an operation is described to be performed, or an effect such as a structure is described to be established “by” or “through” performing additional operations, it will be understood that the operation may be performed and/or the effect/structure may be established “based on” the additional operations, which may include performing said additional operations alone or in combination with other further additional operations.

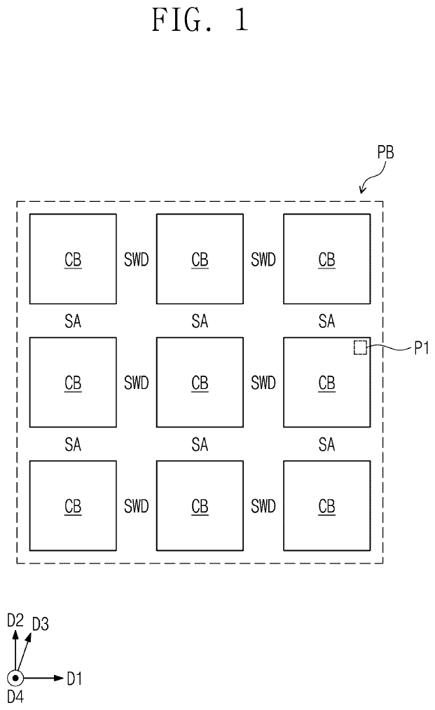

FIG. 1 is a block diagram illustrating a semiconductor device according to some example embodiments of the inventive concepts.

Referring to FIG. 1, a semiconductor device may include cell blocks CB and a peripheral block PB enclosing each of the cell blocks CB. Each of the cell blocks CB may include a cell circuit, such as a memory integrated circuit. The peripheral block PB may include various peripheral circuits, which are used to operate the cell circuit, and the peripheral circuits may be electrically connected to the cell circuit.

The peripheral block PB may include sense amplifier circuits SA and sub-word line driver circuits SWD. In some example embodiments, the sense amplifier circuits SA may be provided to face each other, with the cell blocks CB interposed therebetween, and the sub-word line driver circuits SWD may be provided to face each other, with the cell blocks CB interposed therebetween. The peripheral block PB may further include power and ground circuits for driving a sense amplifier, but the inventive concepts are not limited to this example.

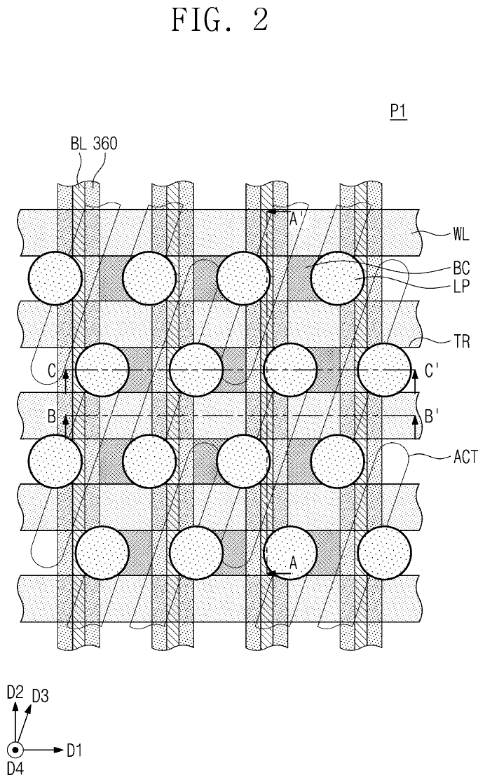

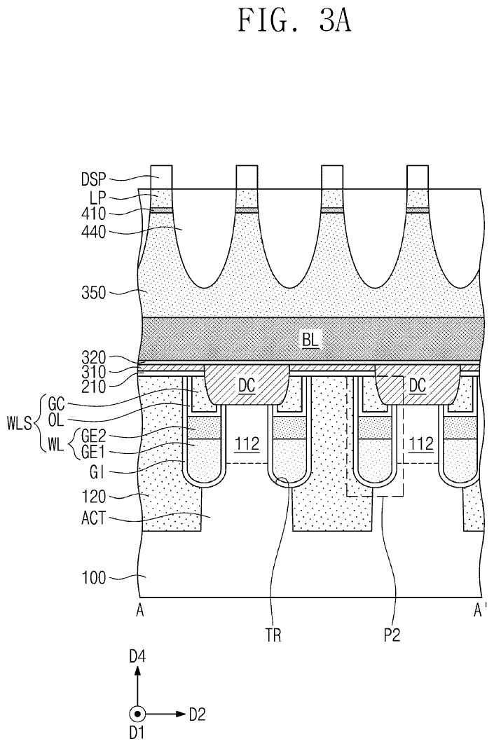

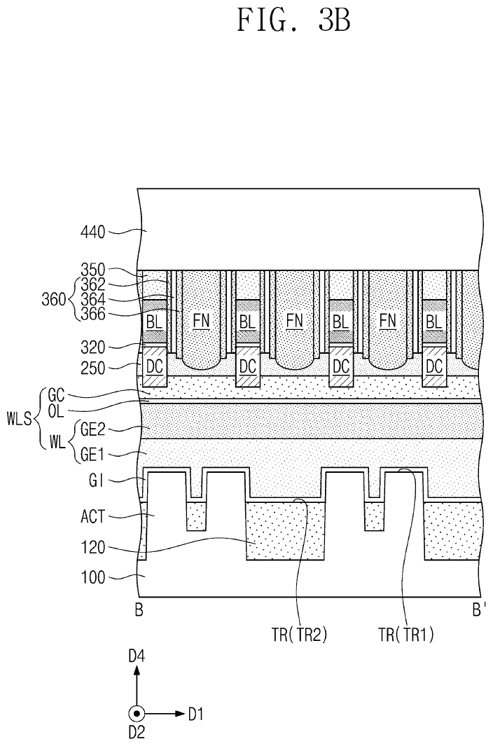

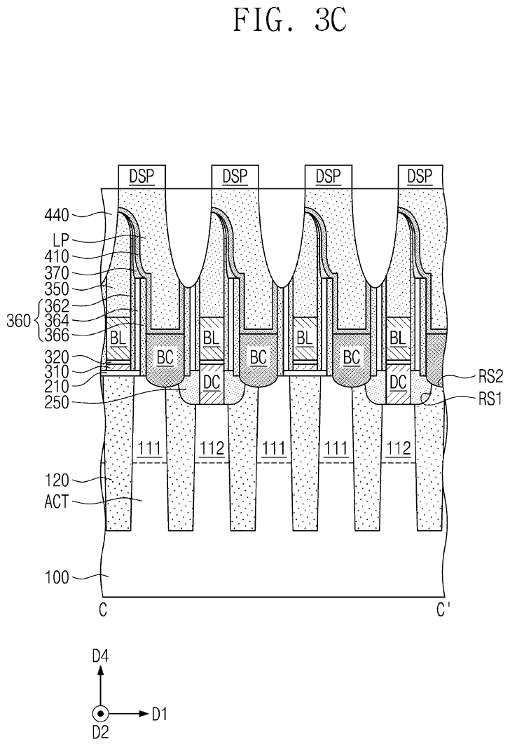

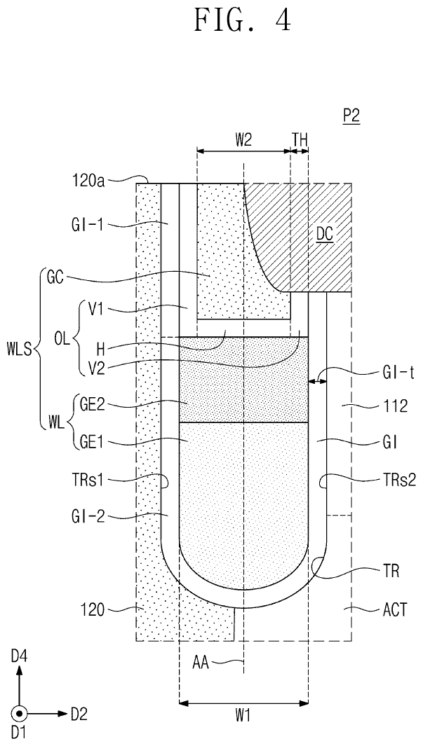

FIG. 2 is a plan view illustrating a semiconductor device according to some example embodiments of the inventive concepts and corresponding to a portion ‘P1’ of FIG. 1. FIGS. 3A, 3B, and 3C are sectional views, which are taken along lines A-A′, B-B′, and C-C′, respectively, of FIG. 2 to illustrate a semiconductor device according to some example embodiments of the inventive concepts. FIG. 4 is an enlarged view corresponding to a portion ‘P2’ of FIG. 3A according to some example embodiments of the inventive concepts.

Referring to FIGS. 2 and 3A to 3C, a substrate 100 may be provided. The substrate 100 may be a semiconductor substrate (e.g., a silicon wafer, a germanium wafer, or a silicon-germanium wafer).

A device isolation pattern 120 may be disposed on the substrate 100 to define active patterns ACT (e.g., such that outer surfaces of the device isolation pattern 120 contact the substrate 100). The active patterns ACT may be provided on the cell blocks CB of FIG. 1. The active patterns ACT may be spaced apart from each other in a first direction D1 and a second direction D2. The active patterns ACT may be bar- or island-shaped patterns, which are spaced apart from each other and are elongated in a third direction D3.

In the present specification, the first direction D1 may be defined to be parallel to a top surface of the substrate 100 and/or an in-plane direction of the substrate 100. The second direction D2 may be defined as a direction that is parallel to the top surface of the substrate 100 and/or an in-plane direction of the substrate 100 and is perpendicular to the first direction D1. The third direction D3 may be defined as a direction that is parallel to the top surface of the substrate 100 and/or an in-plane direction of the substrate 100 and is not parallel to the first and second directions D1 and D2. A fourth direction D4 may be defined to be perpendicular to the top surface of the substrate 100 and/or an in-plane direction of the substrate 100.

The active patterns ACT may have a shape protruding in the fourth direction D4. In some example embodiments, the device isolation pattern 120 may be disposed in the substrate 100, and the active patterns ACT may be portions of the substrate 100 enclosed by the device isolation pattern 120. For the sake of convenience in explanation, the term “substrate 100” may refer to the remaining portion of the substrate 100, excluding the active patterns ACT, unless otherwise stated, such that the active patterns ACT may be referred to as being “on” the substrate 100 (e.g., the remaining portion of the substrate 100 excluding the device isolation pattern and the portions of the substrate 100 enclosed by the device isolation pattern 120).

The device isolation pattern 120 may be formed of or include at least one insulating material (e.g., silicon oxide, silicon nitride, or combinations thereof). The device isolation pattern 120 may be a single layer, which is made of a single material, or a composite layer including two or more materials.

Each of the active patterns ACT may include a pair of edge portions 111 and a center portion 112. The pair of edge portions 111 may be opposite end portions of the active pattern ACT in the third direction D3. The center portion 112 may be a portion of the active pattern ACT, which is placed between a pair of the edge portions 111, and in detail, the center portion 112 may be a portion of the active pattern ACT, which is placed between a pair of word line structures WLS to be described below. The pair of edge portions 111 and/or the center portion 112 may be doped with impurities to have an n- or p-type conductivity.

The word line structures WLS may be disposed to cross the active patterns ACT. In some example embodiments, the word line structure WLS may be provided to cross the active patterns ACT and the device isolation pattern 120 in the first direction D1. In some example embodiments, a plurality of word line structures WLS may be provided. The word line structures WLS may be spaced apart from each other in the second direction D2. In some example embodiments, a pair of the word line structures WLS, which are adjacent to each other in the second direction D2, may be provided to cross one active pattern ACT and which may each at least partially overlap the one active pattern in the first direction D4.

The word line structure WLS may be disposed in a trench region TR, which is formed to cross the active patterns ACT and the device isolation pattern 120. The trench region TR may be extended in the first direction D1. The trench region TR may include a first trench region TR1 and a second trench region TR2. A bottom surface of the first trench region TR1 may be disposed at a level that is higher than a bottom surface of the second trench region TR2. In the present specification, the term “level” may be defined as a height measured from a bottom surface of the substrate 100 (e.g., a distance measured from the bottom surface of the substrate 100 in the fourth direction D4). The first trench region TR1 may be disposed on the active patterns ACT, and the second trench region TR2 may be disposed on the device isolation pattern 120.

Each of the word line structures WLS may include a word line WL, a protection insulating pattern OL, and a gate capping pattern GC. The word line structure WLS may be disposed in the trench region TR crossing the active patterns ACT and the device isolation pattern 120.

The word line WL may be disposed in the lowermost portion of the word line structure WLS. In the present specification, the word line WL may be referred to as the gate electrode WL. The word line WL may include a first conductive pattern GE1 and a second conductive pattern GE2, which are sequentially stacked on the trench region TR (e.g., on the bottom surface of the trench region TR).

The first conductive pattern GE1 may include a metal material and a nitride material (e.g., a separate nitride material) containing the metal material. In some example embodiments, the metal material may be formed of or include at least one of titanium (Ti), molybdenum (Mo), tungsten (W), copper (Cu), aluminum (Al), tantalum (Ta), ruthenium (Ru), or iridium (Ir). The second conductive pattern GE2 may be formed of or include doped poly silicon.

The gate capping pattern GC may be disposed on the word line WL to fill an upper portion of the trench region TR. In some example embodiments, the gate capping pattern GC may be formed of or include silicon nitride.

The protection insulating pattern OL may be disposed on the word line WL to enclose (e.g., contact some or all of) bottom and side surfaces of the gate capping pattern GC. For example, the protection insulating pattern OL may be disposed between (e.g., directly or indirectly between) the word line WL and the gate capping pattern GC. The second conductive pattern GE2 may be spaced apart from the gate capping pattern GC, with the protection insulating pattern OL interposed therebetween. The protection insulating pattern OL may include an insulating material, and in some example embodiments, it may be formed of or include silicon oxide (e.g., SiO₂).

A gate insulating pattern GI may be provided to conformally cover an inner surface of the trench region TR. In detail, the gate insulating pattern GI may be interposed between the word line WL and the active patterns ACT, between the protection insulating pattern OL and the active patterns ACT, between the word line WL and the device isolation pattern 120, and between the protection insulating pattern OL and the device isolation pattern 120. In other words, the protection insulating pattern OL may be disposed between the gate insulating pattern GI and the gate capping pattern GC. As shown in FIGS. 3A and 4, a top surface of the protection insulating pattern OL may be located at the same or substantially the same level as top surfaces of the gate insulating pattern GI and the gate capping pattern GC. The gate insulating pattern GI may be formed of or include at least one of silicon oxide or high-k dielectric materials, or combinations thereof.

Referring to FIG. 4, the protection insulating pattern OL may include a first vertical portion V1, a second vertical portion V2, and a horizontal portion H connecting the first vertical portion V1 to the second vertical portion V2.

The first and second vertical portions V1 and V2 may be provided on the word line WL to each be in contact with a separate side surface of the gate capping pattern GC. The first and second vertical portions V1 and V2 may be disposed between (e.g., directly or indirectly between) the gate insulating pattern GI and the gate capping pattern GC.

The horizontal portion H may be disposed between (e.g., directly or indirectly between) the second conductive pattern GE2 and the gate capping pattern GC. A top surface of the horizontal portion H may be in contact with the bottom surface of the gate capping pattern GC. A bottom surface of the horizontal portion H may be in contact with a top surface of the second conductive pattern GE2. In other words, the second conductive pattern GE2 may be disposed between (e.g., directly or indirectly between) the first conductive pattern GE1 and the horizontal portion H.

The word line WL may have a first width W1 in the second direction D2. The bottom surface of the gate capping pattern GC may have a second width W2 in the second direction D2. Due to the protection insulating pattern OL enclosing the gate capping pattern GC, the second width W2 may be smaller than the first width W1. That is, the largest width of the gate capping pattern GC in the second direction D2 may be smaller than the largest width of the word line WL in the second direction D2.

Here, a thickness TH of the protection insulating pattern OL may be 5% to 40% of the first width W1. The first width W1 may be substantially equal to a sum of the second width W2 and two times the thickness TH of the protection insulating pattern OL.

When measured in the second direction D2, a sum of a thickness TH of the protection insulating pattern OL and a thickness GI-t of the gate insulating pattern GI, which is placed on the word line WL (e.g., a first portion GI-1 of the gate insulating pattern GI that is above the word line WL in the fourth direction D4), may be larger than a thickness of the gate insulating pattern GI, which is placed below the protection insulating pattern OL (e.g., a second portion GI-2 of the gate insulating pattern GI that is below the protection insulating pattern OL in the fourth direction D4).

A buffer pattern 210 may be disposed on the substrate 100. The buffer pattern 210 may cover the active patterns ACT, the device isolation pattern 120, and the word line structures WLS. Here, the buffer pattern 210 may be in contact with the protection insulating pattern OL. In some example embodiments, the buffer pattern 210 may be formed of or include at least one of silicon oxide, silicon nitride, silicon oxynitride, or combinations thereof. The buffer pattern 210 may be a single layer, which is made of a single material, or a composite layer including two or more materials.

A bit line contact DC may be provided on each of the active patterns ACT, and in some example embodiments, a plurality of bit line contacts DC may be provided. The bit line contacts DC may be connected to the center portions 112 of the active patterns ACT, respectively. In the present specification, the expression “A is connected to B” may be used to not only represent “A is in contact with B” but also represent that “A is electrically connected to B” although they are not in physical contact with each other. The bit line contacts DC may be spaced apart from each other in the first and second directions D1 and D2. The bit line contact DC may be interposed between each of the active patterns ACT and a corresponding one of bit lines BL, which will be described below. Each of the bit line contacts DC may connect a corresponding one of the bit lines BL to the center portion 112 of a corresponding one of the active patterns ACT.

The bit line contacts DC may be disposed in first recess regions RS1, respectively. The first recess regions RS1 may be provided in upper portions of the active patterns ACT and an upper portion of the device isolation pattern 120, which is adjacent to the upper portions of the active patterns ACT. The first recess regions RS1 may be spaced apart from each other in the first and second directions D1 and D2.

A gapfill insulating pattern 250 may fill each of the first recess regions RS1. The gapfill insulating pattern 250 may fill an inner space of the first recess region RS1. As an example, the gapfill insulating pattern 250 may cover an inner surface of the first recess region RS1 and at least a portion of a side surface of the bit line contact DC (e.g., in the first recess region RS1). The gapfill insulating pattern 250 may be formed of or include at least one of silicon oxide, silicon nitride, or combinations thereof. The gapfill insulating pattern 250 may be a single layer, which is made of a single material, or a composite layer including two or more materials.

The bit line BL may be provided on the bit line contact DC. The bit line BL may be extended in the second direction D2. The bit line BL may be disposed on the bit line contacts DC, which are arranged in the second direction D2 to form a line. In some example embodiments, a plurality of bit lines BL may be provided. The bit lines BL may be spaced apart from each other in the first direction D1. The bit line BL may include a metal material. For example, the bit line BL may be formed of or include at least one of tungsten, rubidium, molybdenum, titanium, or combinations thereof.

A polysilicon pattern 310 may be provided between the bit line BL and the buffer pattern 210 and between the bit line contacts DC, which are adjacent to each other in the second direction D2. In some example embodiments, a plurality of polysilicon patterns 310 may be provided. The polysilicon patterns 310 may be spaced apart from each other in the first and second directions D1 and D2. A top surface of the polysilicon pattern 310 may be located at substantially the same height as a top surface of the bit line contact DC and may be coplanar with the top surface of the bit line contact DC. The polysilicon pattern 310 may be formed of or include doped polysilicon.

A first barrier pattern 320 may be provided between the bit line BL and the bit line contact DC and between the bit line BL and the polysilicon pattern 310. The first barrier pattern 320 may be extended along the bit lines BL or in the second direction D2. In some example embodiments, a plurality of first barrier patterns 320 may be provided to be spaced apart from each other. The first barrier patterns 320 may be spaced apart from each other in the first direction D1. The first barrier pattern 320 may be formed of or include at least one of conductive metal nitride materials (e.g., titanium nitride and tantalum nitride). A first ohmic pattern (not shown) may be additionally interposed between the bit line BL and the bit line contact DC and between the bit line BL and the polysilicon pattern 310. The first ohmic pattern may be formed of or include at least one of metal silicide materials.

A bit line capping pattern 350 may be provided on a top surface of the bit line BL. On the top surface of the bit line BL, the bit line capping pattern 350 may be extended in the second direction D2. In some example embodiments, a plurality of bit line capping patterns 350 may be provided. The bit line capping patterns 350 may be spaced apart from each other in the first direction D1. The bit line capping pattern 350 may be vertically overlapped with the bit line BL. The bit line capping pattern 350 may be composed of a single layer or a plurality of layers.

A bit line spacer 360 may be provided on a side surface of the bit line BL and a side surface of the bit line capping pattern 350. The bit line spacer 360 may cover the side surface of the bit line BL and the side surface of the bit line capping pattern 350. The bit line spacer 360 on the side surface of the bit line BL may be extended in the second direction D2. In some example embodiments, a plurality of bit line spacers 360 may be provided. The bit line spacers 360 may be spaced apart from each other in the first direction D1.

Each of the bit line spacers 360 may include a plurality of spacers. As an example, each of the bit line spacers 360 may include a first spacer 362, a second spacer 364, and a third spacer 366. The first spacer 362 may be provided on the side surface of the bit line BL and the side surface of the bit line capping pattern 350. The third spacer 366 may be provided on side surfaces of a storage node contact BC and a second barrier pattern 410, which will be described below. The second spacer 364 may be interposed between the first spacer 362 and the third spacer 366. In some example embodiments, each of the first to third spacers 362, 364, and 366 may be independently formed of or include at least one of silicon nitride, silicon oxide, silicon oxynitride, or combinations thereof. In some example embodiments, the second spacer 364 may include an air gap separating the first and third spacers 362 and 366 from each other.

A capping spacer 370 may be placed on the bit line spacer 360. In some example embodiments, the capping spacer 370 may be formed of or include silicon nitride.

The storage node contact BC may be provided between adjacent ones of the bit lines BL. As an example, the storage node contact BC may be interposed between adjacent ones of the bit line spacers 360. In some example embodiments, a plurality of storage node contacts BC may be provided. The storage node contacts BC may be spaced apart from each other in the first and second directions D1 and D2. The storage node contacts BC may be spaced apart from each other in the second direction D2, by fence patterns FN on the word line structures WLS. The fence pattern FN may be provided between adjacent ones of the bit lines BL. In some example embodiments, a plurality of fence patterns FN may be provided. The fence patterns FN may be spaced apart from each other in the first and second directions D1 and D2. The fence patterns FN, which are adjacent to each other in the first direction D1, may be spaced apart from each other, with the bit line BL interposed therebetween. The fence patterns FN, which are adjacent to each other in the second direction D2, may be spaced apart from each other, with the storage node contact BC interposed therebetween. In some example embodiments, the fence patterns FN may be formed of or include silicon nitride.

The storage node contact BC may fill a second recess region RS2, which is provided on the edge portion 111 of the active pattern ACT. The storage node contact BC may be connected to the edge portion 111. The storage node contact BC may be formed of or include at least one of doped or undoped polysilicon, metallic materials, or combinations thereof.

A second barrier pattern 410 may conformally cover the bit line spacer 360 and the storage node contact BC. The second barrier pattern 410 may be formed of or include at least one of metal nitride materials (e.g., titanium nitride and tantalum nitride). A second ohmic pattern (not shown) may be further interposed between the second barrier pattern 410 and the storage node contact BC. The second ohmic pattern may be formed of or include at least one of metal silicide materials.

A landing pad LP may be provided on the storage node contact BC. In some example embodiments, a plurality of landing pads LP may be provided. The landing pads LP may be spaced apart from each other in the first and second directions D1 and D2. The landing pad LP may be electrically connected to the corresponding storage node contact BC. The landing pad LP may cover a top surface of the bit line capping pattern 350. A lower region of the landing pad LP may be vertically overlapped with the storage node contact BC. An upper region of the landing pad LP may be shifted from the lower region in the first direction D1. The landing pad LP may be formed of or include at least one of metallic materials (e.g., tungsten, titanium, and tantalum).

A filler pattern 440 may be provided to enclose the landing pad LP. The filler pattern 440 may be interposed between adjacent ones of the landing pads LP. When viewed in a plan view, the filler pattern 440 may be provided in a mesh shape with holes, and in this case, the landing pads LP may be provided in the holes to penetrate the filler pattern 440. As an example, the filler pattern 440 may be formed of or include at least one of silicon nitride, silicon oxide, silicon oxynitride, or combinations thereof. As another example, the filler pattern 440 may include an empty space with an air layer (i.e., an air gap).

A data storage pattern DSP may be provided on the landing pad LP. In some example embodiments, a plurality of data storage patterns DSP may be provided. The data storage patterns DSP may be spaced apart from each other in the first and second directions D1 and D2. Each of the data storage patterns DSP may be connected to a corresponding one of the edge portions 111 through a corresponding one of the landing pads LP and a corresponding one of the storage node contacts BC.

In some example embodiments, the data storage pattern DSP may be a capacitor including a bottom electrode, a dielectric layer, and a top electrode. In this case, the semiconductor memory device may be a dynamic random access memory (DRAM) device. As another example, the data storage pattern DSP may include a magnetic tunnel junction pattern. In this case, the semiconductor memory device may be a magnetic random access memory (MRAM) device. As other examples, the data storage pattern DSP may include a phase-change material or a variable resistance material. In this case, the semiconductor memory device may be a phase-change random access memory (PRAM) device or a resistive random access memory (ReRAM) device. However, the inventive concepts are not limited to these examples, and the data storage pattern DSP may include various structures and/or materials that can be used to store data therein.

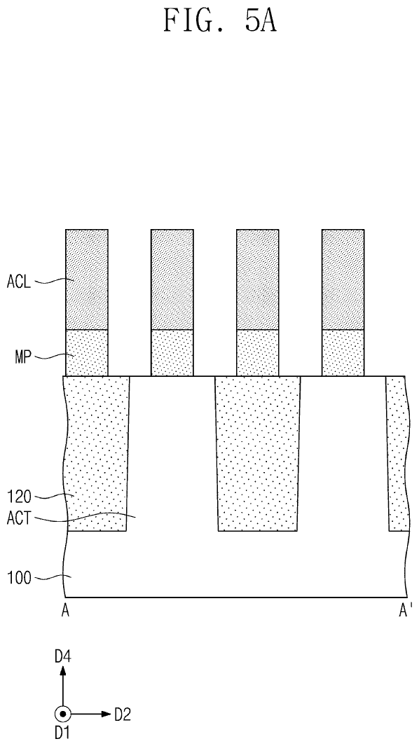

FIGS. 5A, 5B, 6A, 6B, 7A, 7B, 8A, 8B, 9A, 9B, 10A, 10B, 11A, 11B, 12A, 12B, 13A, and 13B are sectional views illustrating a process of fabricating a semiconductor device, according to some example embodiments of the inventive concepts. In detail, FIGS. 5A, 6A, 7A, 8A, 9A, 10A, 11A, 12A, and 13A are sectional views corresponding to the line A-A′ of FIG. 2. FIGS. 5B, 6B, 7B, 8B, 9B, 10B, 11B, 12B, and 13B are sectional views corresponding to the line B-B′ of FIG. 2.

Referring to FIGS. 5A and 5B, the substrate 100 may be prepared. The device isolation pattern 120 may be formed to be buried in an upper portion of the substrate 100. The formation of the device isolation pattern 120 may include patterning the upper portion of the substrate 100 to form an isolation trench and forming the device isolation pattern 120 to fill the isolation trench. Remaining portions of the upper portion of the substrate 100, which are enclosed by the device isolation pattern 120, may be defined as the active patterns ACT. Impurity regions may be formed in the active patterns ACT. The formation of the impurity regions may include injecting impurities into the active patterns ACT through an ion implantation process.

A mask layer (not shown) and a carbon thin layer (not shown) may be formed on the active patterns ACT and the device isolation pattern 120. The mask layer (not shown) may be formed closer to the substrate 100 than the carbon thin layer (not shown). Thereafter, a carbon thin pattern ACL and a mask pattern MP may be formed by patterning the carbon thin layer (not shown) and the mask layer (not shown). The carbon thin pattern ACL and the mask pattern MP may define a region in which the word line structure WLS will be formed.

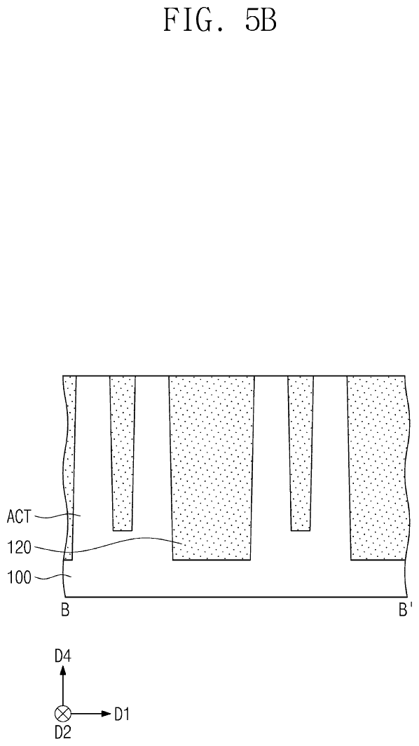

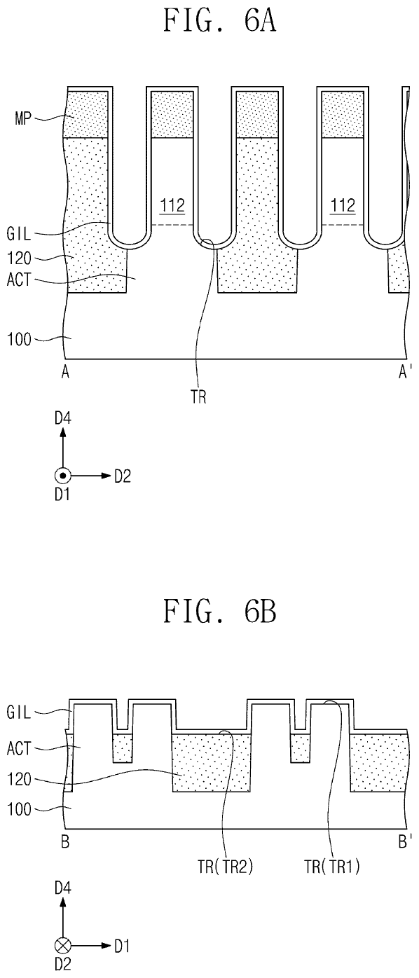

Referring to FIGS. 6A and 6B, upper portions of the active patterns ACT and an upper portion of the device isolation pattern 120 may be etched using the carbon thin pattern ACL as an etch mask. The trench regions TR may be formed on the substrate 100 by the etching process. The trench regions TR may be extended in the first direction D1 and may be spaced apart from each other in the second direction D2. Here, a bottom surface of each of the trench regions TR may be formed to have a non-flat shape. In some example embodiments, the trench region TR may include the first trench region TR1 on the active pattern ACT and the second trench region TR2 on the device isolation pattern 120. The bottom surface of the first trench region TR1 may be formed at a level higher than the bottom surface of the second trench region TR2. Etch rates of the active pattern ACT and the device isolation pattern 120 may be different from each other, when the etching process is performed, and thus, the bottom surfaces of the first and second trench regions TR1 and TR2 may be formed at different levels.

Owing to the trench regions TR, each of the active patterns ACT may be classified into a pair of edge portions 111 and a center portion 112, as shown in FIG. 3C. The pair of the edge portions 111 may be defined in opposite edge regions of each of the active patterns ACT. The center portion 112 may be defined between a pair of the trench regions TR. Thereafter, the carbon thin pattern ACL may be removed.

A gate insulating layer GIL may be conformally formed on the substrate 100. In detail, the gate insulating layer GIL may conformally cover (e.g., may contact) inner surfaces of the trench regions TR and may be extended along (e.g., on, directly on, etc.) side surfaces of the active patterns ACT and a side surface of the device isolation pattern 120 to cover the top and side surfaces of the mask patterns MP. The gate insulating layer GIL may be formed using a physical vapor deposition (PVD) process, a chemical vapor deposition (CVD) process, or an atomic layer deposition (ALD) process.

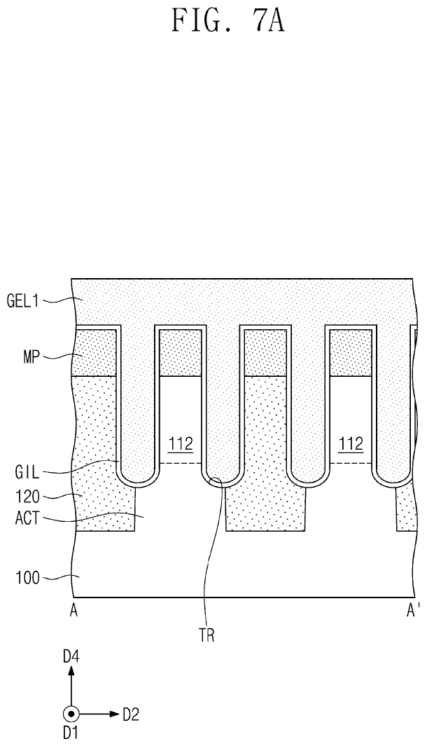

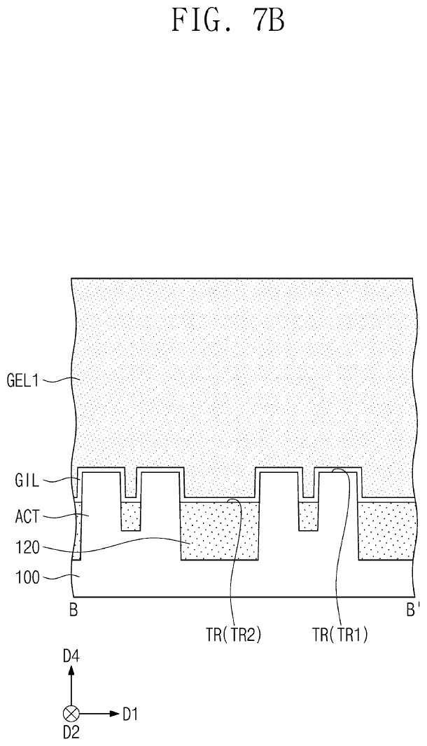

Referring to FIGS. 7A and 7B, a first conductive layer GEL1 may be formed to fill the trench regions TR. In some example embodiments, the first conductive layer GEL1 may be formed to fill the trench regions TR and to cover the mask pattern MP and the gate insulating layer GIL. The formation of the first conductive layer GEL1 may include performing a physical vapor deposition (PVD) process, a chemical vapor deposition (CVD) process, or an atomic layer deposition (ALD) process.

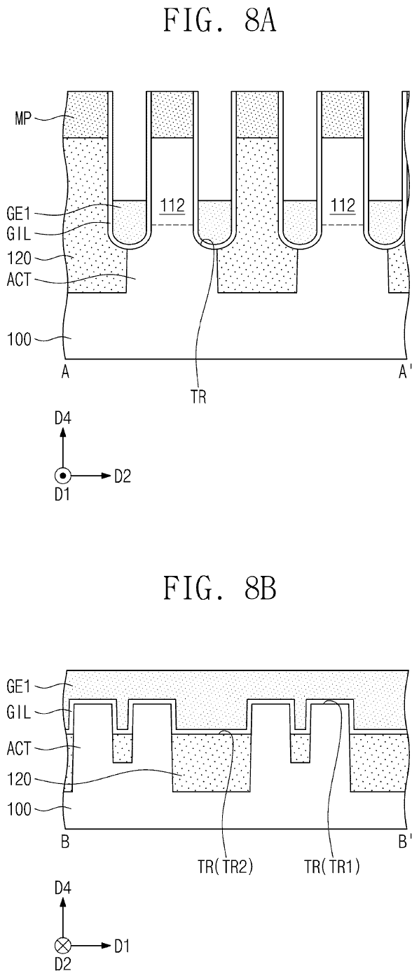

Referring to FIGS. 8A and 8B, an upper portion of the first conductive layer GEL1 may be etched to form a plurality of first conductive patterns GE1. The etching of the upper portion of the first conductive layer GEL1 may include performing an etch-back process on the first conductive layer GEL1. Thus, the first conductive pattern GE1 may be formed to fill a lower portion of the trench region TR. Top surfaces of the first conductive patterns GE1 may be placed at the same or substantially the same level (e.g., may be coplanar or substantially coplanar with each other), but the inventive concepts are not limited to this example. The gate insulating layer GIL on a top surface of the mask pattern MP and a portion of the mask pattern MP may be removed, as a result of the etching process.

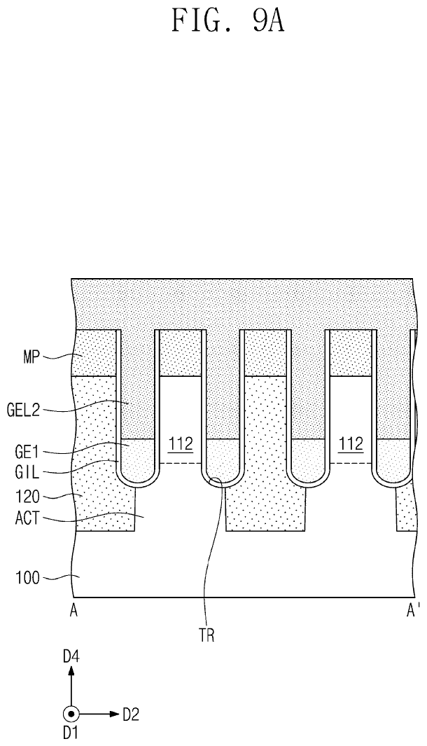

Referring to FIGS. 9A and 9B, a second conductive layer GEL2 may be formed in the trench regions TR and on the first conductive patterns GE1. The second conductive layer GEL2 may fill the trench regions TR on the first conductive patterns GE1 and may cover the top surface of the mask pattern MP. The formation of the second conductive layer GEL2 may include performing a physical vapor deposition (PVD) process, a chemical vapor deposition (CVD) process, or an atomic layer deposition (ALD) process.

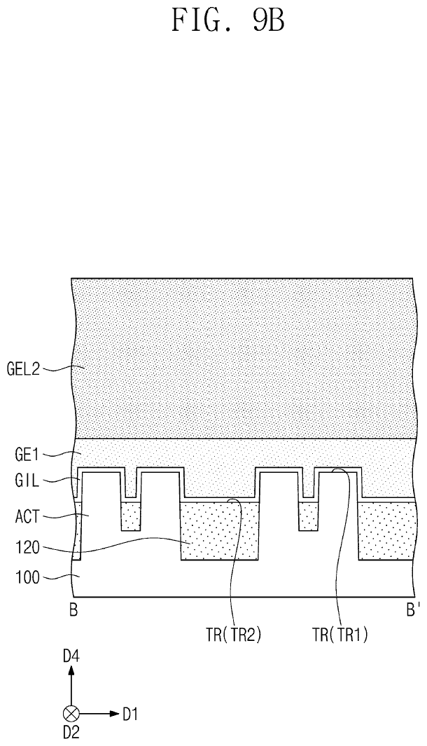

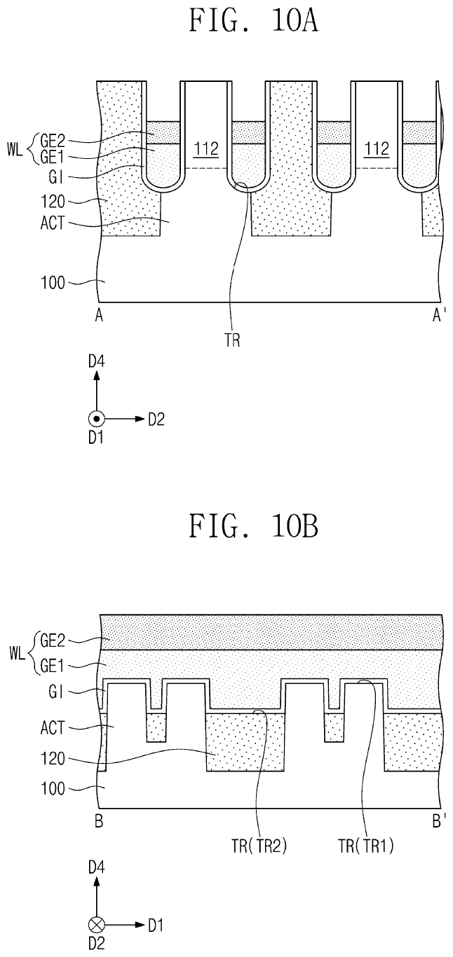

Referring to FIGS. 10A and 10B, an upper portion of the second conductive layer GEL2 may be etched to form a plurality of second conductive patterns GE2. The etching of the upper portion of the second conductive layer GEL2 may include performing an etch-back process on the second conductive layer GEL2. Thus, the second conductive pattern GE2 may fill the trench region TR, on the first conductive pattern GE1. Top surfaces of the second conductive patterns GE2 may be formed at the same or substantially the same level, but the inventive concepts are not limited to this example. The mask pattern MP and a portion of the gate insulating layer GIL, which covers a side surface of the mask pattern MP, may be removed, as a result of the etching process. The word line WL, which includes the first and second conductive patterns GE1 and GE2, may be formed, as a result of the formation of the second conductive pattern GE2. The gate insulating pattern GI may be formed, as a result of the partial removal of the gate insulating layer GIL. FIGS. 10A and 10B illustrate an example, in which the mask pattern MP on the substrate 100 is fully removed by the etching process, but the inventive concepts are not limited to this example. Although not shown, a portion of the mask pattern MP may be left on the substrate 100, after the etching process, and in this case, a thickness of the left mask pattern MP may be measured, after the formation of the second conductive pattern GE2.

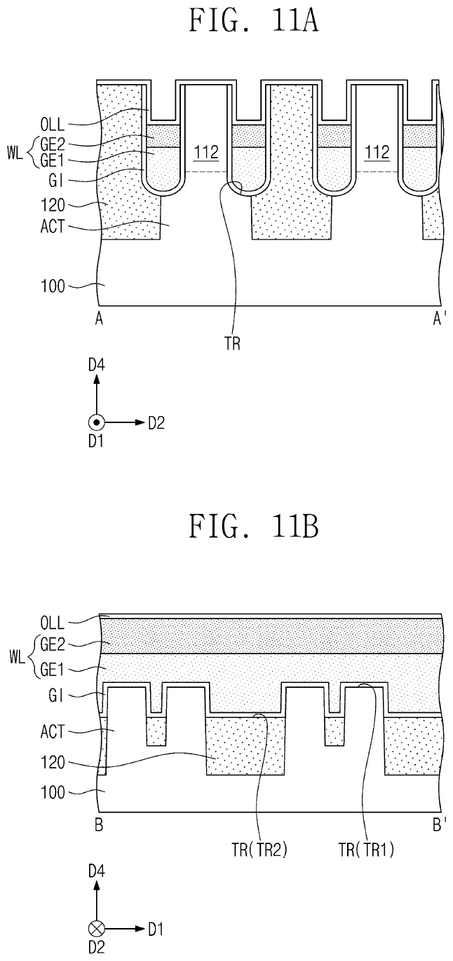

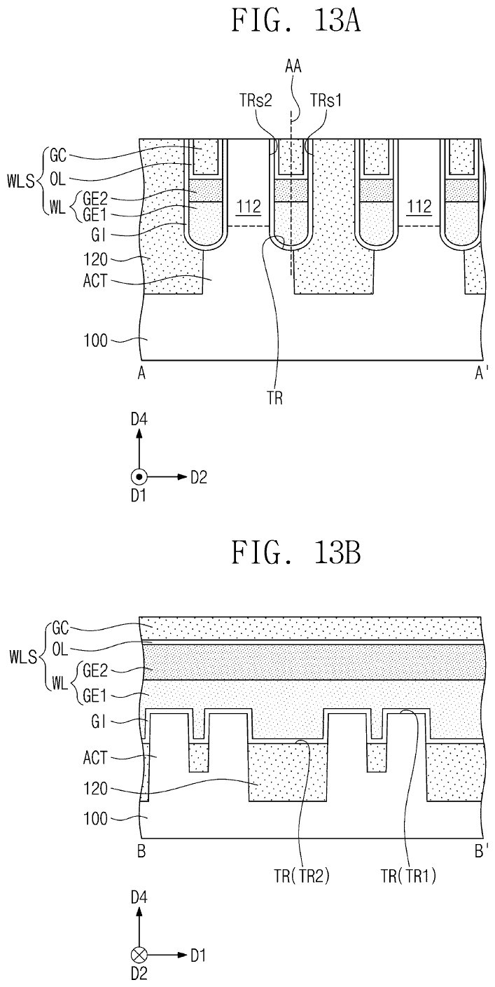

Referring to FIGS. 11A and 11B, a protection insulating layer OLL may be formed on the word line WL. In detail, the protection insulating layer OLL may cover a top surface of the second conductive pattern GE2, an upper portion of a side surface of the gate insulating pattern GI, a top surface of the device isolation pattern 120, and a top surface of the active pattern ACT. Here, the protection insulating layer OLL may be used as an etch mask in an etch-back process on a gate capping layer GCL to be described with reference to FIGS. 13A and 13B, and a thickness of the protection insulating layer OLL may correspond to a thickness of the etch mask, which may be configured or required to protect the substrate 100 during the etch-back process. The formation of the protection insulating layer OLL may include performing an atomic layer deposition (ALD) process. Thereafter, a thermal treatment process may be performed on the word line WL and the protection insulating layer OLL.

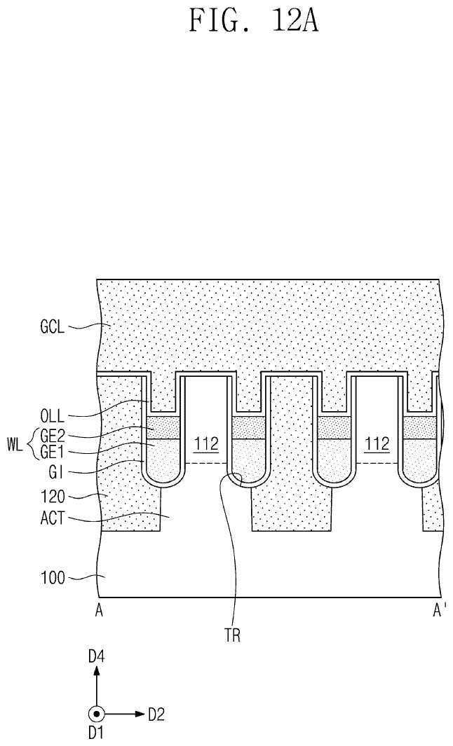

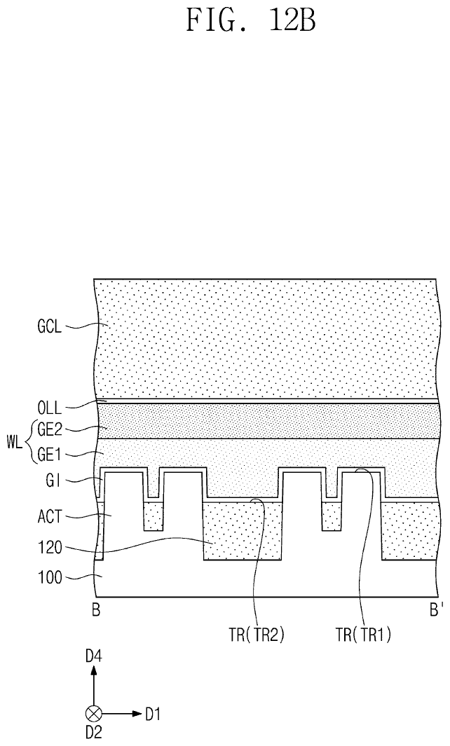

Referring to FIGS. 12A and 12B, the gate capping layer GCL may be formed on the protection insulating layer OLL. In detail, the gate capping layer GCL may fill a remaining space of the trench region TR, excluding the protection insulating layer OLL and the word line WL, and may cover the uppermost surface of the protection insulating layer OLL.

Referring to FIGS. 13A and 13B, an upper portion of the gate capping layer GCL may be etched to form a plurality of gate capping patterns GC. The etching of the upper portion of the gate capping layer GCL may include performing an etch-back process on the gate capping layer GCL. Thus, the gate capping pattern GC may be formed on the second conductive pattern GE2 to fill the trench region TR. The etching process may be performed to remove a portion of the protection insulating layer OLL, which is placed on (e.g., directly or indirectly on) the top surfaces of the device isolation pattern 120 and the active pattern ACT. As a result of the partial removal of the protection insulating layer OLL, the protection insulating pattern OL may be formed. The word line WL, the protection insulating pattern OL, and the gate capping pattern GC may form the word line structure WLS.

Thereafter, referring to FIGS. 13A, 13B, and 3A to 3C, a buffer layer (not shown) and a poly-silicon layer (not shown) may be formed to cover the active patterns ACT and the device isolation pattern 120, and the first recess region RS1 may be formed on each of the active patterns ACT and the device isolation pattern 120. Here, the buffer layer and the poly-silicon layer may be partially removed to form the buffer pattern 210 and the polysilicon pattern 310.

The bit line contact DC, the first barrier pattern 320, the bit line BL, and the bit line capping pattern 350 may be formed on the first recess region RS1. The formation of the bit line contact DC, the first barrier pattern 320, the bit line BL, and the bit line capping pattern 350 may include forming a bit line contact layer (not shown) to fill the first recess region RS1, sequentially forming a first barrier layer (not shown), a bit line layer (not shown), and a bit line capping layer (not shown) on the bit line contact layer, and etching the bit line contact layer, the first barrier layer, the bit line layer, and the bit line capping layer to form the bit line contact DC, the first barrier pattern 320, the bit line BL, and the bit line capping pattern 350. Here, a portion of the polysilicon pattern 310 may be further etched. During this process, an inner portion of the first recess region RS1 may be partially exposed to the outside. Thereafter, the gapfill insulating pattern 250 may be formed to fill a remaining portion of the first recess region RS1. A first ohmic pattern (not shown) may be further formed between the bit line BL and the bit line contact DC and between the bit line BL and the polysilicon pattern 310, in a process of forming the bit line BL.

The bit line spacer 360 may be formed to cover the side surface of the bit line BL and the side surface of the bit line capping pattern 350. The formation of the bit line spacer 360 may include sequentially forming the first spacer 362, the second spacer 364, and the third spacer 366 to conformally cover the side surface of the bit line BL and the bit line capping pattern 350.

The storage node contacts BC and the fence patterns FN may be formed between adjacent ones of the bit lines BL. The storage node contacts BC and the fence patterns FN may be alternatively arranged in the second direction D2. Each of the storage node contacts BC may be formed to fill the second recess region RS2 and may be electrically connected to a corresponding edge portion 111 of the active pattern ACT in the second recess region RS2. The fence patterns FN may be formed at positions that are vertically overlapped with the word line structures WLS. In some example embodiments, the storage node contacts BC may be formed first, and then the fence patterns FN may be formed between the storage node contacts BC. In some example embodiments, the fence patterns FN may be formed first, and then the storage node contacts BC may be formed between the fence patterns FN.

An upper portion of the bit line spacer 360 may be partially removed during the formation of the storage node contacts BC. In this case, the capping spacer 370 may be additionally formed in a region, which is formed by removing the bit line spacer 360. Thereafter, the second barrier pattern 410 may be formed to conformally cover the bit line spacer 360, the capping spacer 370, and the storage node contacts BC.

The landing pads LP may be formed on the storage node contacts BC. The formation of the landing pads LP may include sequentially forming a landing pad layer (not shown) and mask patterns (not shown) to cover the top surfaces of the storage node contacts BC and performing an anisotropic etching process using the mask patterns as an etch mask to form a plurality of landing pads LP from the landing pad layer. Additionally, the second barrier pattern 410, the bit line spacer 360, and the bit line capping pattern 350 may be partially etched through an etching process and may be exposed to the outside. An upper portion of the landing pad LP may be shifted from the storage node contact BC in the first direction D1.

In some example embodiments, the etching process on the landing pad layer may be performed to expose the second spacer 364. The second spacer 364 may be further etched through the exposed portion of the second spacer 364, and in this case, a final structure of the second spacer 364 may include an air gap. However, the inventive concepts are not limited to this example.

Thereafter, the filler pattern 440 may be formed to cover exposed surfaces of the resulting structure and to enclose each of the landing pads LP, and the data storage patterns DSP may be formed on the landing pads LP, respectively.

In a semiconductor fabrication process according to a comparative example, when a trench region, which is a space for a word line structure, is formed, a mask layer may be thickly formed to prevent a substrate from being damaged in a subsequent etching process (e.g., see FIG. 5A). However, if the mask layer is thick, there may be a difficulty in forming the trench region (e.g., TR as shown in FIGS. 3A, 3B, 4, 6A, and 6B, 13A and 13B) to have a uniform etching profile. As shown in at least FIG. 13A, a trench region TR having a uniform etching profile may have a symmetric profile in at least a plane extending in the second and fourth directions D2 and D4 as shown in at least FIG. 13A, such that the trench region TR has mirror symmetry (also referred to as reflection symmetry) in at least the second direction D2 across or around an axis or plane of symmetry AA extending in the fourth direction D4. The axis or plane of symmetry AA may extend along (e.g., coaxial with) a centerline of the trench region TR such that the axis or plane of symmetry AA is equidistant from opposing first and second inner side surfaces TRs1 and TRs2 of the trench region TR in the second direction D2. As shown, the first inner side surface TRs1 may be defined by an inner surface of the device isolation pattern 120 and the second inner side surface TRs2 may be defined by an inner surface of the active pattern ACT). For example, based on the mask layer (e.g., used to form mask pattern MP in FIG. 5A) being thick in the fourth direction D4, the trench region (TR) may have an asymmetric section (e.g., an asymmetric profile in at least a plane extending in the second and fourth directions D2 and D4), such that the trench region TR may lack mirror symmetry in the second direction D2 across or around any axis or plane that extends in the fourth direction D4 between opposing first and second inner side surfaces TRs1 and TRs2 of the trench region TR. As a result, a word line WL filling such a trench region TR that has an asymmetric section may also be formed to have an asymmetric section (e.g., an asymmetric profile in at least a plane extending in the second and fourth directions D2 and D4), and this may lead to deterioration in the electrical/operational characteristics of the semiconductor device. In addition, a portion of a side surface of a gate insulating pattern GI may be damaged in a process of forming the word line, and this may lead to a leakage current issue.

By contrast, in the semiconductor fabrication process according to some example embodiments of the inventive concepts, a word line WL may be formed, and then, a protection insulating layer OLL may be formed on a top surface of the word line (e.g., as shown in FIGS. 3A-3B, 4, and 11A-11B), a side surface of a gate insulating pattern GI, and an active pattern ACT. The protection insulating layer OLL may prevent a top surface of a substrate 100 from being damaged in a step of etching a gate capping layer (e.g., the step shown in FIGS. 13A and 13B), or reduce or minimize such damage. As a result, a mask (e.g., forming mask pattern MP in FIG. 5A) with a reduced thickness in the fourth direction D4 may be used in a process of forming the trench region TR, and thus, the trench region TR may be formed to have a uniform section or symmetric section (e.g., a symmetric profile in at least a plane extending in the second and fourth directions D2 and D4) as shown in at least FIG. 13A. As a result, and as shown in at least FIG. 13A, the trench region TR may be formed to have mirror symmetry (also referred to as reflection symmetry) across or around an axis or plane of symmetry AA extending in the fourth direction D4 along a centerline of the trench region TR equidistantly between opposing first and second inner side surfaces TRs1 and TRs2 of the trench region TR in the second direction D2, based on the presence of the protection insulting layer OLL during the etching step (e.g., shown in FIGS. 13A and 13B). As a result, and as further shown in FIG. 13A and also in FIGS. 3A and 4, a word line WL filling such a trench region TR may also be formed to have a uniform section (e.g., a symmetric profile in at least a plane extending in the second and fourth directions D2 and D4) such that the word line WL has mirror symmetry in the second direction D2 around or across the axis or plane of symmetry AA that extends in the fourth direction D4 through the trench TR (e.g., equidistantly between the opposing inner surfaces TRs1 and TRs2 of the trench TR). Such symmetrical structure of the word line WL may reduce, minimize, or prevent deterioration in the electrical/operational characteristics of the semiconductor device. Thus, the performance and reliability of a semiconductor device may be improved based on including the protection insulating pattern OL (which is formed from the partial removal of the protection insulting layer OLL during the etching of the upper portion of the gate capping layer GCL as shown in FIGS. 13A and 13B), which promotes formation of a word line WL that has mirror symmetry in the second direction D2. Furthermore, even when a side surface of the gate insulating pattern GI is damaged during forming the word line, the protection insulating layer OLL (which forms the protection insulating pattern) may reduce, minimize or prevent a leakage current issue despite such damage, which is caused by the damage of the gate insulating pattern, thereby further improving the performance and reliability of a semiconductor device based on including the protection insulating pattern OL. In addition, the protection insulating layer may prevent impurities in poly silicon from being diffused to the outside (or reduce or minimize such diffusion), based on a thermal treatment process being performed on the word line, and this may make it possible to improve the electrical and reliability characteristics of the semiconductor device based on the semiconductor device including the protection insulting pattern OL.

According to some example embodiments of the inventive concepts, a semiconductor device may include a protection insulating pattern between a word line and a gate capping pattern. A gate insulating pattern may be damaged by a process of forming the gate capping pattern, but the protection insulating pattern, along with the gate insulating pattern, may be used to reduce, minimize, or prevent a leakage current. In addition, the protection insulating pattern may prevent impurities, which are included in the word line, from being diffused to the outside of the word line (or reduce or minimize such diffusion). As a result, the electric and reliability characteristics of the semiconductor device may be improved based on the semiconductor device including the protection insulting pattern.

While some example embodiments of the inventive concepts have been particularly shown and described, it will be understood by one of ordinary skill in the art that variations in form and detail may be made therein without departing from the spirit and scope of the attached claims.

What is claimed is:

1. A semiconductor device, comprising:
a substrate;
an active pattern on the substrate; and
a word line structure crossing the active pattern,
wherein the word line structure includes
a word line,
a capping pattern on the word line, and
a protection insulating pattern between the word line and the capping pattern.

2. The semiconductor device of claim 1, wherein
the word line comprises a first conductive pattern and a second conductive pattern,
the second conductive pattern is between the first conductive pattern and the protection insulating pattern, and
the second conductive pattern is in contact with the protection insulating pattern.

3. The semiconductor device of claim 2, wherein the second conductive pattern is spaced apart from the capping pattern, and the protection insulating pattern is between the second conductive pattern and the capping pattern.

4. The semiconductor device of claim 2, wherein
the first conductive pattern comprises both a metallic material and a separate nitride material, the separate nitride material a nitride of the metallic material,
the metal material comprises at least one of titanium (Ti), molybdenum (Mo), tungsten (W), copper (Cu), aluminum (Al), tantalum (Ta), ruthenium (Ru), or iridium (Ir),
the second conductive pattern comprises doped poly silicon, and
the protection insulating pattern comprises silicon oxide.

5. The semiconductor device of claim 1, further comprising:
a gate insulating pattern extended into a region between the active pattern and the word line,
wherein the protection insulating pattern is in contact with the gate insulating pattern.

6. The semiconductor device of claim 5, further comprising:
a device isolation layer enclosing the active pattern,
wherein the gate insulating pattern is between the device isolation layer and the protection insulating pattern, and the gate insulating pattern is between the active pattern and the protection insulating pattern.

7. A semiconductor device, comprising:
a substrate;
a device isolation pattern on the substrate;
an active pattern on the substrate, the active pattern enclosed by the device isolation pattern; and
a word line structure crossing the device isolation pattern and the active pattern in a first direction, the first direction parallel to a top surface of the substrate,
wherein the word line structure includes
a word line,
a capping pattern on the word line, and
a protection insulating pattern on the word line, the protection insulating pattern enclosing bottom and side surfaces of the capping pattern,
wherein the word line has a first width in a second direction, the second direction parallel to the top surface of the substrate and perpendicular to the first direction,
wherein a bottom surface of the capping pattern has a second width in the second direction, and
wherein the second width is smaller than the first width.

8. The semiconductor device of claim 7, wherein a thickness of the protection insulating pattern is 5% to 40% of a length of the first width.

9. The semiconductor device of claim 8, wherein a length of the first width is equal to a sum of a length of the second width and two times the thickness of the protection insulating pattern.

10. The semiconductor device of claim 7, further comprising:
a buffer pattern covering each of the active pattern, the device isolation pattern, and the word line,
wherein the buffer pattern is in contact with the protection insulating pattern.

11. The semiconductor device of claim 7, further comprising:
a gate insulating pattern extended into a space between the active pattern and the word line,
wherein a level of a top surface of the protection insulating pattern is equal to a level of a top surface of the gate insulating pattern.

12. The semiconductor device of claim 11, wherein the protection insulating pattern is between the gate insulating pattern and the capping pattern.

13. The semiconductor device of claim 11, wherein the gate insulating pattern and the protection insulating pattern each comprise silicon oxide.

14. A semiconductor device, comprising:
a substrate;
a device isolation pattern on the substrate;
an active pattern on the substrate, the active pattern enclosed by the device isolation pattern;
a word line structure crossing the active pattern and the device isolation pattern in a first direction parallel to a top surface of the substrate;
a bit line on the active pattern and extended in a second direction crossing the first direction;
a bit line contact between the active pattern and the bit line;
a storage node contact on the active pattern;
a landing pad on the storage node contact; and
a capacitor on the landing pad,
wherein the word line structure includes
a first conductive pattern,
a second conductive pattern on the first conductive pattern,
a capping pattern on the second conductive pattern, and
a protection insulating pattern between the second conductive pattern and the capping pattern,
wherein the protection insulating pattern includes a first vertical portion, a second vertical portion, and a horizontal portion connecting the first vertical portion to the second vertical portion,
wherein the first and second vertical portions are each in contact with a side surface of the capping pattern, and
wherein the horizontal portion is in contact with a bottom surface of the capping pattern.

15. The semiconductor device of claim 14, further comprising:
a gate insulating pattern extended into a space between the active pattern and the word line structure,
wherein the first and second vertical portions of the protection insulating pattern are between the gate insulating pattern and the capping pattern.

16. The semiconductor device of claim 14, wherein top surfaces of the first and second vertical portions of the protection insulating pattern are at a same level as a top surface of the capping pattern.

17. The semiconductor device of claim 14, wherein the horizontal portion of the protection insulating pattern is between the second conductive pattern and the capping pattern.

18. The semiconductor device of claim 14, wherein the second conductive pattern is between the first conductive pattern and the horizontal portion of the protection insulating pattern.

19. The semiconductor device of claim 14, wherein a bottom surface of the horizontal portion of the protection insulating pattern is in contact with a top surface of the second conductive pattern.

20. The semiconductor device of claim 15, wherein a sum of a thickness of the protection insulating pattern in the second direction and a thickness of a first portion of the gate insulating pattern that is above a word line of the word line structure in the second direction is larger than a thickness of a second portion of the gate insulating pattern that is below the protection insulating pattern, in the second direction.
